(19) United States
(12) Patent Application Publication
(10) Pub. No.: US 2025/0120078 A1
(43) Pub. Date: Apr. 10, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Nam Jae LEE, Gyeonggi-do (KR)

(21) Appl. No.: 18/391,657

(22) Filed: Dec. 21, 2023

(30) Foreign Application Priority Data
Oct. 4, 2023 (KR) 10-2023-0131624

(51) Int. Cl. H10B 43/27; H10B 41/10; H10B 41/27; H10B 43/10; H10B 63/00

(52) U.S. Cl. CPC H10B 43/27; H10B 41/10; H10B 41/27; H10B 43/10; H10B 63/84

(57) ABSTRACT

A semiconductor device may include a gate structure including gate lines and insulating layers alternately stacked, a channel structure extending through the gate structure and including a channel layer and a channel pad connected to the channel layer, a dummy gate structure including stacked dummy gate lines, a dummy channel structure extending through the dummy gate structure and including a dummy channel layer and a dummy channel pad connected to the dummy channel layer, an isolation insulating layer disposed between the gate structure and the dummy gate structure, and a dummy pad disposed on the isolation insulating layer between the gate structure and the dummy gate structure.

### CROSS-REFERENCE TO RELATED APPLICATION

This application claims priority under 35 U.S.C. § 119 to Korean Patent Application No. 10-2023-0131624 filed on Oct. 4, 2023, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a gate structure including gate lines and insulating layers alternately stacked, a channel structure extending through the gate structure and including a channel layer and a channel pad connected to the channel layer, a dummy gate structure including stacked dummy gate lines, a dummy channel structure extending through the dummy gate structure and including a dummy channel layer and a dummy channel pad connected to the dummy channel layer, an isolation insulating layer disposed between the gate structure and the dummy gate structure, and a dummy pad disposed on the isolation insulating layer between the gate structure and the dummy gate structure.

According to an embodiment of the present disclosure, a semiconductor device may include a gate structure including gate lines and insulating layers alternately stacked, a dummy gate structure including stacked dummy gate lines, an isolation insulating structure disposed between the gate structure and the dummy gate structure and including stacked horizontal portions and vertical portions extending through the horizontal portions, and a dummy pad disposed on the isolation insulating structure between the gate structure and the dummy gate structure.

According to an embodiment of the present disclosure, a method of manufacturing a semiconductor device may include forming a stack including first material layers and second material layers alternately stacked, forming first openings in the stack, etching the first material layers exposed through the first openings to form second openings interconnecting the first openings, forming an insulating layer in the first openings and the second openings, etching the insulating layer to form an isolation insulating layer, and forming a dummy pad on the isolation insulating layer.

According to an embodiment of the present disclosure, a method of manufacturing a semiconductor device may include forming a stack including a block edge region, a block center region, and a boundary region disposed between the block edge region and the block center region, forming openings in the stack, forming a channel material layer in the openings, etching a portion disposed in the boundary region of the channel material layer to separate the channel material layer into a dummy channel layer disposed in the block edge region and a channel layer disposed in the block center region, forming an isolation trench in the boundary region, forming an insulating layer in the isolation trench, the channel layer, and the dummy channel layer, forming third openings by partially etching the insulating layer, and forming pads in the third openings.

These and other features and advantages will become apparent from the following figures and detailed description of example embodiments of the present invention.

### BRIEF DESCRIPTION OF THE DRAWINGS

FIGS. 1A and 1B are diagrams illustrating a structure of a semiconductor device according to an embodiment of the present disclosure.

FIGS. 2A to 2D are diagrams illustrating a method of manufacturing a semiconductor device according to an embodiment of the present disclosure.

FIGS. 3A to 9A and FIGS. 3B to 9B are diagrams illustrating a method of manufacturing a semiconductor device according to an embodiment of the present disclosure.

### DETAILED DESCRIPTION

Embodiments of the present disclosure provide a semiconductor device and a method of manufacturing the semiconductor device having a stable structure and improved characteristic.

An integration degree of a semiconductor device may be improved by stacking memory cells in a three dimension. In addition, a semiconductor device with a stable structure and improved reliability may be provided.

Hereinafter, embodiments according to the technical spirit of the present disclosure are described with reference to the accompanying drawings.

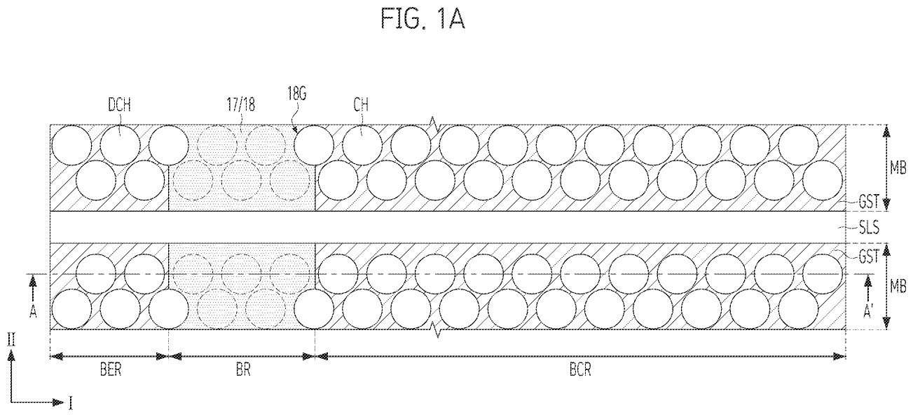

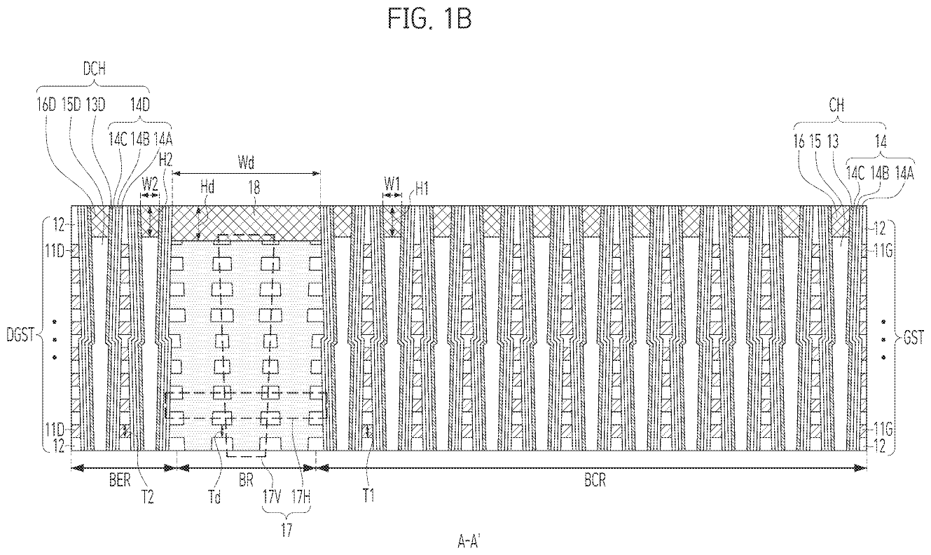

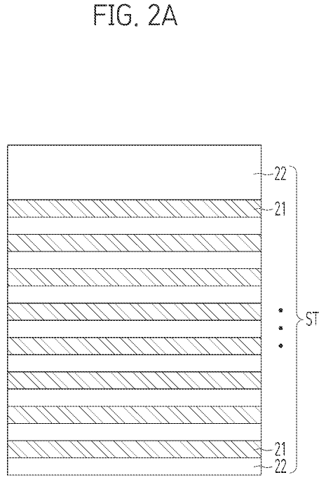

FIGS. 1A and 1B are diagrams illustrating a structure of a semiconductor device according to an embodiment of the present disclosure. FIG. 1B is an A-A′ cross-sectional view of FIG. 1A.

Referring to FIGS. 1A and 1B, the semiconductor device may include a gate structure GST, a channel structure CH, a dummy gate structure DGST, a dummy channel structure DCH, an isolation insulating layer 17, a dummy pad 18, and a slit structure SLS. The semiconductor device may be a chip and may include a plurality of planes. Each plane may include a plurality of memory blocks MB. Each memory block MB may include a block center region BCR, a block edge region BER, and a boundary region BR disposed between the block center region BCR and the block edge region BER. The block center region BCR and the block edge region BER may be adjacent to each other in a first direction I, and the block edge region BER may be disposed closer to an edge of the plane compared to the block center region BCR. When two features are said to be adjacent in a certain direction as this term is used herein, it means that the two features are close or near to each other but they may not necessarily be in direct contact to each other. Hence, for example, the block center region BCR and the block edge region BER are close to each other in the first direction but they are separated by the boundary region BR. More specifically, the boundary region BR may be disposed at a boundary of the block center region BCR and the block edge region BER. A portion including the boundary may be defined as the boundary region BR, and the boundary region BR may be disposed between the block center region BCR and the block edge region BER.

The gate structure GST may be disposed in the block center region BCR. The gate structure GST may include gate lines 11G and insulating layers 12 alternately stacked. The gate lines 11G may be a word line, a source selection line, a drain selection line, and the like. The gate lines 11G may include a conductive material such as polysilicon, tungsten, or molybdenum. The insulating layers 12 may insulate the stacked gate lines 11G from each other. Suitable insulating materials for the insulating layers 12d may include an oxide, or a nitride. However, the insulating layers 12 may also include a void and/or a combination of an insulating material and a void.

The channel structure CH may extend through the gate structure GST. The channel structure CH may include a channel layer 13 and a channel pad 16 connected to the channel layer 13. The channel layer 13 may include a semiconductor material such as silicon or germanium. The channel pad 16 may be formed in the channel layer 13 and may be in direct contact with the channel layer 13. The channel pad 16 may be used as a pad for connecting the channel layer to a line such as a bit line. The channel pad 16 may include a conductive material and a junction doped with an impurity of an N-type or a P-type. In some embodiments, the channel pad 16 may include polysilicon.

The channel structure CH may further include at least one of a memory layer 14 surrounding the channel layer 13 and an insulating core 15 in the channel layer 13. The memory layer 14 may include a floating gate, polysilicon, a charge trap material, nitride, a variable resistance material, or the like. For reference, some of the channel structures CH passing through the gate structure GST may be dummy channel structures. In some embodiments, among the channel structures CH, the channel structures CH disposed adjacent to the isolation insulating layer 17 may be a dummy channel structure.

The dummy gate structure DGST may be disposed in the block edge region BER. The dummy gate structure DGST may include stacked dummy gate lines 11D. The dummy gate lines 11D may be disposed at a level corresponding to the gate lines 11G. The insulating layers 12 may extend between the dummy gate lines 11D, and the dummy gate lines 11D and the insulating layers 12 may be alternately stacked. The dummy gate lines 11D may include a conductive material such as polysilicon, tungsten, or molybdenum.

The dummy channel structure DCH may extend through the dummy gate structure DGST. The dummy channel structure DCH may have a structure similar to the channel structure CH. The dummy channel structure DCH may include a dummy channel layer 13D and a dummy channel pad 16D connected to the dummy channel layer 13D. The dummy channel pad 16D may be formed in the dummy channel layer 13D and may be in direct contact with the dummy channel layer 13D. The dummy channel pad 16D may include a conductive material and a junction doped with an impurity of an N-type or a P-type. In some embodiments, the dummy channel pad 16D may include polysilicon. The dummy channel structure DCH may further include at least one of a dummy memory layer 14D and a dummy insulating core 15D. The dummy memory layer 14D may include a floating gate, polysilicon, a charge trap material, nitride, a variable resistance material, or the like.

The isolation insulating layer 17 may be disposed in the boundary region BR. The isolation insulating layer 17 may be disposed between the gate structure GST and the dummy gate structure DGST which are adjacent in the first direction I. The isolation insulating layer 17 may electrically isolate the gate structure GST and the dummy gate structure DGST. The isolation insulating layer 17 may include an insulating material such as oxide or nitride.

The isolation insulating layer 17 may include horizontal portions 17H and vertical portions 17V. The horizontal portions 17H may be stacked between the gate structure GST and the dummy gate structure DGST. The horizontal portions 17H may be disposed to correspond to the gate lines 11G and the dummy gate lines 11D, and may be disposed between the gate lines 11G and the dummy gate lines 11D. A thickness Td of the horizontal portion 17H may be substantially the same as a thickness T1 of the gate line 11G and a thickness T2 of the dummy gate line 11D. The insulating layers 12 may extend between the horizontal portions 17H, and the horizontal portions 17H and the insulating layers 12 may be alternately stacked.

The vertical portions 17V may extend through the horizontal portions 17H. The vertical portion 17V may have a shape substantially the same as the channel structure CH and the dummy channel structure DCH. At the same level, a width of the vertical portion 17V may be substantially the same as a width of the channel structure CH and a width of the dummy channel structure DCH.

The dummy pad 18 may be disposed on the isolation insulating layer 17 between the gate structure GST and the dummy gate structure DGST. The dummy pad 18 may be formed together when forming the channel pad 16 and/or the dummy channel pad 16D. The dummy pad 18 may be disposed between the channel pad 16 and the dummy channel pad 16D, and may be disposed at substantially the same level as the channel pad 16 and the dummy channel pad 16D. In some embodiments, an upper surface of the dummy pad 18 may be disposed at substantially the same level as an upper surface of the channel pad 16. The upper surface of the dummy pad 18 may be disposed at substantially the same level as an upper surface of the dummy channel pad 16D.

The dummy pad 18 may have a larger size compared to the channel pad 16 and the dummy channel pad 16D. A width Wd of the dummy pad 18 may be greater than a width W1 of the channel pad 16 and a width W2 of the dummy channel pad 16D. A height Hd of the dummy pad 18 may be greater than a height H1 of the channel pad 16 and a height H2 of the dummy channel pad 16D.

The dummy pad 18 may include a groove 18G on a sidewall. The channel structure CH and the dummy channel structure DCH disposed adjacent to the dummy pad 18 may protrude toward the dummy pad 18, and the channel structure CH or the dummy channel structure DCH may be disposed in the groove 18G.

The dummy pad 18 may include the same material as the channel pad 16 and the dummy channel pad 16D. For example, in some embodiments, the dummy pad 18, the channel pad 16, and the dummy channel pad 16D may include polysilicon.

The slit structure SLS may be disposed between memory blocks MB which are adjacent in a second direction II. Here, the second direction II may be a direction crossing the first direction I, for example, the second direction II may be orthogonal to the first direction I. The slit structure SLS may be disposed between the gate structures GST, and may extend between the isolation insulating structures IS and between the dummy gate structures DGST. The slit structure SLS may extend along the first direction I. The slit structure SLS may extend from the block center region BCR to the boundary region BR and the block edge region BER. The gate structures GST adjacent in the second direction II may be insulated from each other by the slit structure SLS. The slit structure SLS may include at least one of an insulating material, a semiconductor material, and a conductive material.

According to the structure described above, the isolation insulating layer 17 and the dummy pad 18 may be disposed between the gate structure GST and the dummy gate structure DGST adjacent in the first direction I. Therefore, the gate structures GST may be separated from each other by the isolation insulating layer 17 and the dummy pad 18.

A pattern density at which the dummy channel structures DCH are disposed in the block edge region BER and a pattern density at which the channel structures CH are disposed in the block center region CER may be substantially identical or similar to each other. Therefore, during a manufacturing process, bending of a stack, a slit, or the like of a region with a relatively low pattern density may be reduced. In order to compensate for a pattern density difference, a shape of the slit structure SLS might not be changed, and the slit structure SLS may have a uniform width. In addition, occurrence of wafer warpage may be reduced by positioning the gate structure GST in the block center region BCR and positioning the dummy gate structure DGST in the block edge region BER.

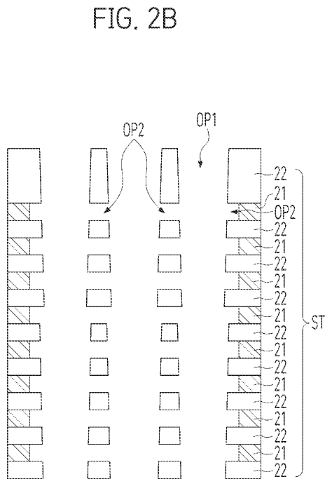

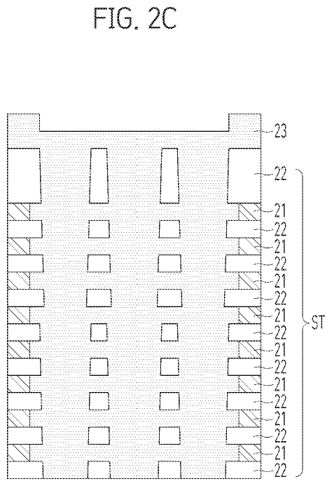

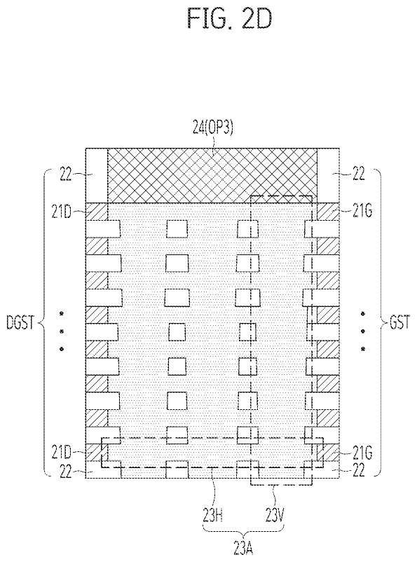

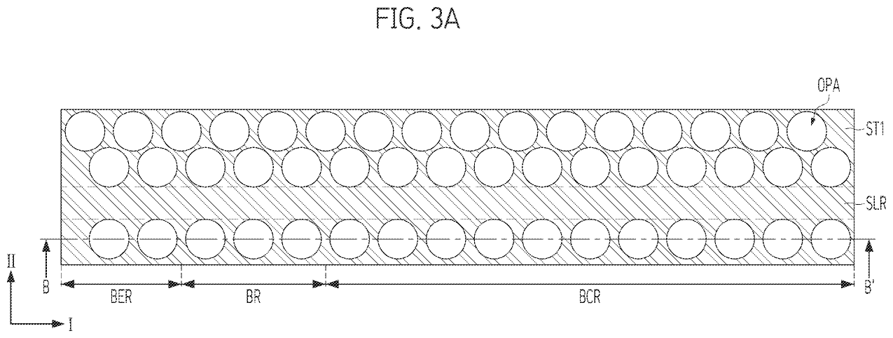

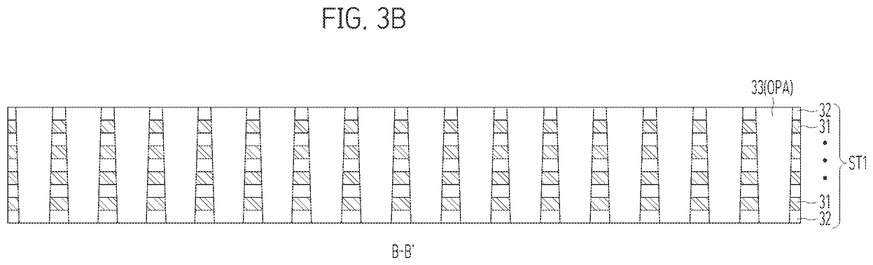

FIGS. 2A to 2D are diagrams illustrating a method of manufacturing a semiconductor device according to an embodiment of the present disclosure. Hereinafter, a description overlapping the content described above may be omitted.

Referring to FIG. 2A, a stack ST may be formed by alternately stacking first and second material layers 21 and 22. The first material layers 21 may be for forming a gate line, and the second material layers 22 may be for insulating stacked gate lines from each other. The first material layers 21 may include a material having a high etch selectivity with respect to the second material layers 22. The first material layers 21 may include a sacrificial material such as nitride, or may include a conductive material such as polysilicon, tungsten, or molybdenum. The second material layers 22 may include an insulating material such as oxide or nitride.

Referring to FIG. 2B, at least one first opening OP1 may be formed in the stack ST. The first opening OP1 may extend vertically through the stack ST. Subsequently, second laterally extending openings OP2 (also referred to as lateral or horizontal openings) may be formed. The second openings OP2 may be formed by etching first material layers 21 exposed through the first openings OP1. Adjacent first openings OP1 may be connected to each other through the second openings OP2.

Referring to FIG. 2C, an insulating layer 23 may be formed. In some embodiments, the insulating layer 23 may be formed in the first openings OP1 and the second openings OP2. The insulating layer 23 may include an insulating material such as oxide, or nitride. In a variation of this embodiment, a void may be formed in the region showing as covered by the insulating layer 23.

Referring to FIG. 2D, an isolation insulating layer 23A may be formed by partially etching the insulating layer 23. When etching the insulating layer 23, the second material layer 22 may be partially etched. A third opening OP3 may be formed in a portion where the insulating layer is etched. The isolation insulating layer 23A may include horizontal portions 23H and vertical portions 23V. The vertical portions 23V may be disposed in the first openings OP1, and the horizontal portions 23H may be disposed in the second openings OP2.

Subsequently, a dummy pad 24 may be formed in the third opening OP3. The dummy pad 24 may be disposed on the isolation insulating layer 23A. In some embodiments, the dummy pad 24 may include polysilicon. For example, the dummy pad 24 may be a doped polysilicon layer including an impurity of an N-type or a P-type.

Subsequently, the first material layers 21 may be replaced with third material layers. In some embodiments, after removing the first material layers 21, conductive layers may be formed as the third material layers. Through this, the gate structure GST including gate lines 21G and second material layers 22 alternately stacked may be formed. At this time, the gate structure GST may be formed on one side of the isolation insulating layer 23A, and the dummy gate structure DGST may be formed on another side. The dummy gate structure DGST may include dummy gate lines 21D and second material layers 22 alternately stacked.

For reference, when the first material layers 21 include a conductive material, a replacement process may be omitted. In this case, the first material layers 21 may be used as the gate line 21G and the dummy gate line 21D, and the stack ST may be used as the gate structure GST.

According to the manufacturing method described above, before replacing the first material layers 21 with the third material layers, the isolation insulating layer 23A and the dummy pad 24 may be formed in the stack ST. Therefore, the replacement process may be performed in a state in which the stack ST is separated into one side and another side of the isolation insulating layer 23A, and the gate structures GST and the dummy gate structures DGST may be naturally separated. The gate structures GST and the dummy gate structures DGST may be formed in a mutually separated form, and a separate process for separating the gate structures GST and the dummy gate structures DGST may be omitted.

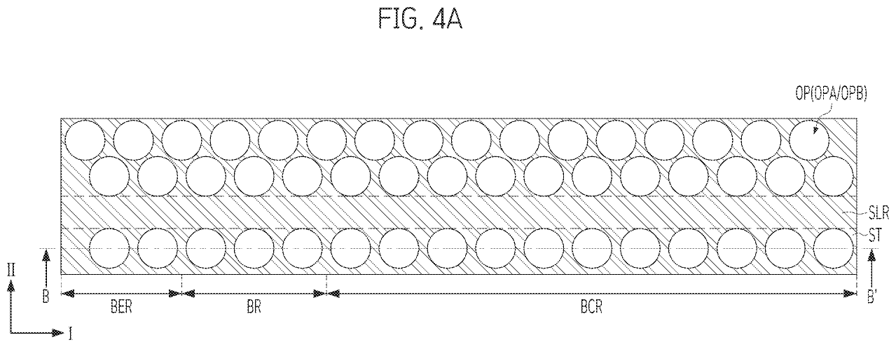

FIGS. 3A to 9A and FIGS. 3B to 9B are diagrams illustrating a method of manufacturing a semiconductor device according to an embodiment of the present disclosure. A diagram of each number is a plan view, and B diagram of each number is a B-B′ cross-sectional view of the A diagram. Hereinafter, a description overlapping the content described above may be omitted.

Referring to FIGS. 3A and 3B, a first sub-stack ST1 may be formed. The first sub-stack ST1 may include first material layers 31 and second material layers 32 alternately stacked. The first material layers 31 may be for forming a gate line, and the second material layers 32 may be for insulating stacked gate lines from each other. The first material layers 31 may include a material having a high etch selectivity with respect to the second material layers 32. The first material layers 31 may include a sacrificial material such as nitride or include a conductive material such as polysilicon or metal. The second material layers 32 may include an insulating material such as oxide or nitride.

The first sub-stack ST1 may include a block center region BCR, a block edge region BER, and a boundary region BR. The boundary region BR may be disposed between the block center region BCR and the block edge region BER.

Subsequently, first sub-openings OPA may be formed in the first sub-stack ST1. The first sub-openings OPA may extend through the first sub-stack ST1. The first sub-openings OPA may be arranged in the first direction I and the second direction II crossing the first direction I. The first sub-openings OPA may be disposed in the block center region BCR, the block edge region BER, and the boundary region BR. The first sub-openings OPA might not be formed in a slit region SLR where a slit is to be formed in a subsequent process.

Subsequently, a sacrificial layer 33 may be formed inside the first sub-openings OPA filling the first sub-openings OPA to their top. The sacrificial layer 33 may include a material having a high etch selectivity with respect to the first and second material layers 31 and 32.

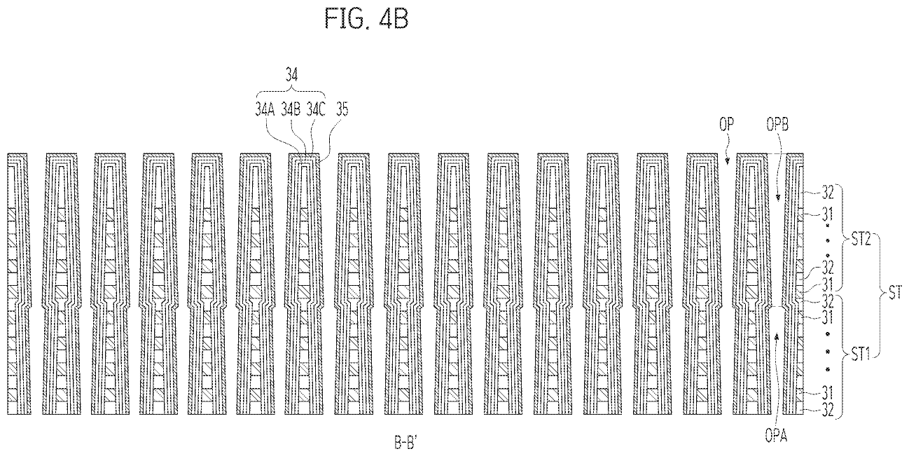

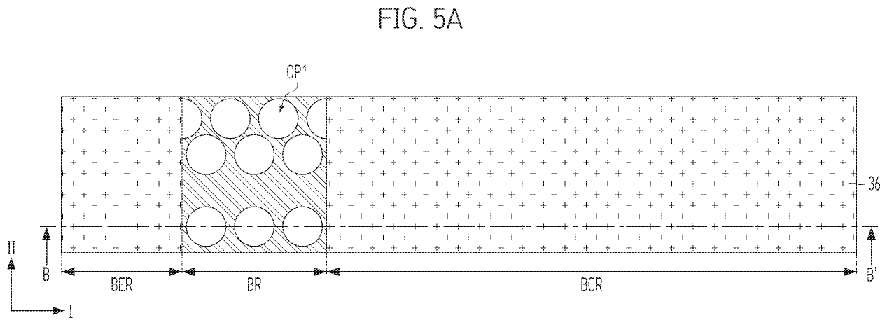

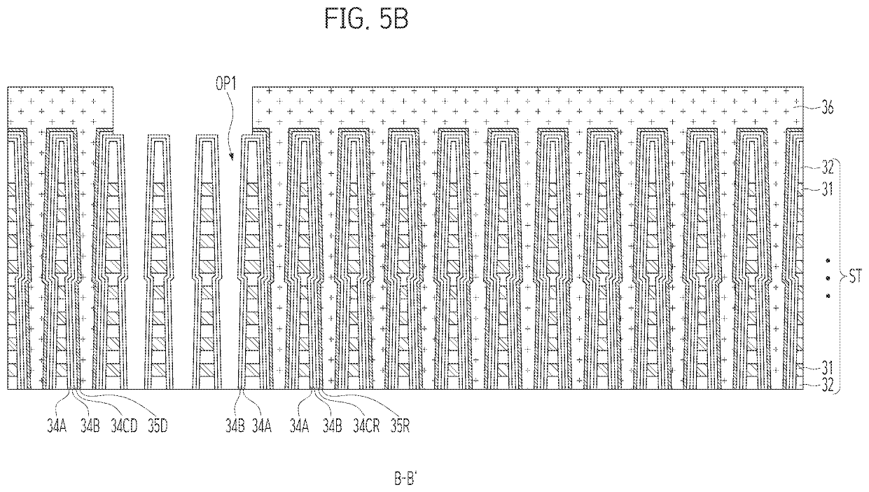

Referring to FIGS. 4A and 4B, a second sub-stack ST2 including first material layers 31 and second material layers 32 alternately stacked may be formed over the first sub-stack 31. The second sub-stack ST2 may include the block center region BCR, the block edge region BER, and the boundary region BR. Through this, a stack ST including the first sub-stack ST1 and the second sub-stack ST2 may be formed.

Subsequently, second sub-openings OPB may be formed in the second sub-stack ST2. The second sub-openings OPB may be connected to the first sub-openings OPA. The second sub-openings OPB might not be formed in the slit region SLR. Each one of the first sub-openings OPA may be connected with a corresponding one of the second sub-openings OPB to form a single continuous opening OP. The openings OP may provide the channel holes for forming the channel structures or may provide the dummy channel holes for forming the dummy channel structures. T Each opening OP may provide a portion of an isolation trench for forming an isolation insulating layer.

Subsequently, a memory material layer 34 and a channel material layer 35 may be formed. More specifically, the memory material layer 34 may be formed first along an inner surface of the openings OP, and then, after forming the memory material layer 34, the channel material layer 35 may be formed over the memory material layer 34. The memory material layer 34 may be formed conformally to form a layer with a substantially constant thickness over the inside surface of the openings OP and also over the top surface of the top second material layer 32. The channel material layer 35 may be formed conformally over the memory material layer 34 to form a layer with a substantially constant thickness. The memory material layer 34 and the channel material layer 35 may be formed in a thickness in which the memory material layer 34 and the channel material layer 35 do not completely fill the opening OP. The memory material layer 34 may be a multilayer structure including at least one of a blocking layer 34A, a data storage layer 34B, and a tunneling layer 34C. In the illustrated embodiment, the memory material layer 34 includes the blocking layer 34A, the data storage layer 34B, and the tunneling layer 34C. The blocking layer 34A may include a high dielectric constant (high-k) material. The data storage layer 34B may include a floating gate, polysilicon, a charge trap material, nitride, a variable resistance material, or the like. The tunneling layer 34C may include oxide. The channel material layer 35 may include a semiconductor material such as, for example, polysilicon.

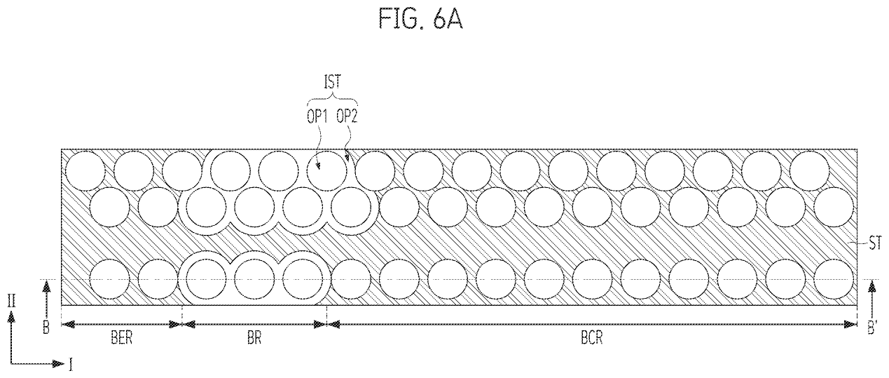

Referring to FIGS. 5A and 5B, a mask pattern 36 may be formed on the stack ST. The mask pattern 36 may cover the block center region BCR and the block edge region BER, and may expose the boundary region BR. The mask pattern 36 may include a photoresist. The mask pattern 36 may be formed to fill the openings OP of the block center region BCR and the block edge region BER.

Subsequently, the channel material layer 35 and the memory material layer 34 may be etched using the mask pattern 36 as an etch barrier. A portion of the memory material layer 34 may be etched. In some embodiments, the data storage layer 34B may be exposed by etching the channel material layer 35 and the tunneling layer 34C. By etching a portion formed in the boundary region BR of the channel material layer 35, the channel material layer 35 may be separated into a channel layer 35R disposed in the block center region BCR and a dummy channel layer 35D disposed in the block edge region BER. By etching a portion formed in the boundary region BR of the tunneling layer 34C, the tunneling layer 34C may be separated into a tunneling layer 34CR disposed in the block center region BCR and a dummy tunneling layer 34CD disposed in the block edge region BER.

Subsequently, the mask pattern 36 may be removed. In some embodiments, the photoresist may be removed using a strip process, and a cleaning process may be performed.

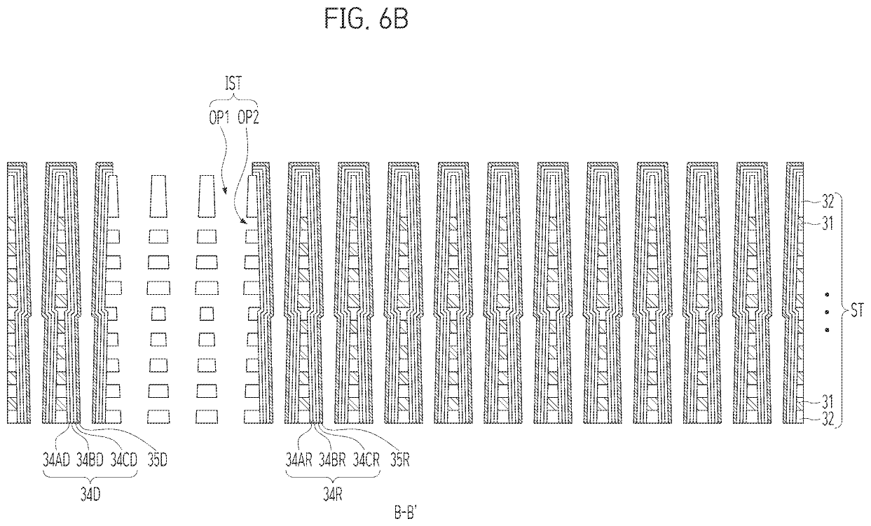

Referring to FIGS. 6A and 6B, the data storage layer 34B of the boundary region BR may be etched to expose the blocking layer 34A. By etching a portion formed in the boundary region BR of the data storage layer 34B, the data storage layer 34B may be separated into a data storage layer 34BR disposed in the block center region BCR and a dummy data storage layer 34BD disposed in the block edge region BER. Subsequently, the blocking layer 34A of the boundary region BR may be etched to expose the first material layers 31 and the second material layers 32. By etching a portion formed in the boundary region BR of the blocking layer 34A, the blocking layer 34A may be separated into a blocking layer 34AR disposed in the block center region BCR and a dummy blocking layer 34AD disposed in the block edge region BER.

Through this, a portion disposed in the boundary region BR of the memory material layer 34 may be selectively etched. A portion disposed in the block edge region BER and the block center region BCT of the memory material layer 34 is covered by the channel layer 35R and the dummy channel layer 35D, and thus the portion disposed in the block edge region BER and the block center region BCT of the memory material layer 34 might not be etched. Therefore, the memory material layer 34 may be separated into a memory layer 34R disposed in the block center region BCR and a dummy memory layer 34D disposed in the block edge region BER.

As the memory material layer 34 is etched, first openings OP1 may be formed in the block edge region BER. Among the openings OP, the openings OP disposed in the block edge region BER may be reopened to form the first openings OP1. The first openings OP1 may be disposed between the channel layer 35R and the dummy channel layer 35D. The first material layers 31 and the second material layers 32 may be exposed through the first openings OP1.

Subsequently, second openings OP2 (also referred to as lateral openings or horizontal openings) may be formed by etching the first material layers 31 exposed through the first openings OP1. The first material layers 31 may be selectively etched to form the second openings OP2. Adjacent first openings OP1 may be connected to each other by the second openings OP2. Through this, an isolation trench IST may be formed in the boundary region BR. The first material layers 31 of the block edge region BER and the first material layers 31 of the block center region BCR may be separated from each other by the isolation trench IST.

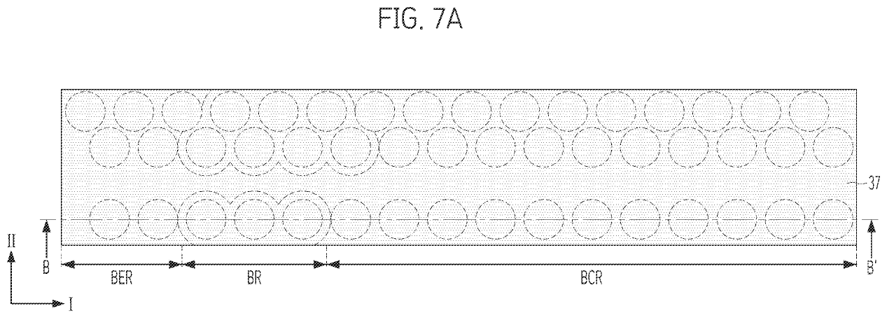

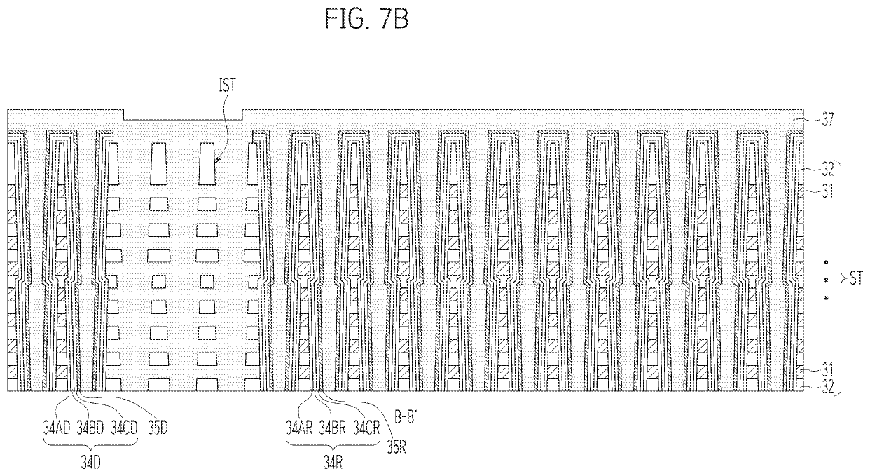

Referring to FIGS. 7A and 7B, an insulating layer 37 may be formed. The insulating layer 37 may be formed in the isolation trench IST. The insulating layer 37 may be formed in the channel layer 35R of the block center region BCR and the dummy channel layer 35D of the block edge region BER. The insulating layer 37 may include an insulating material such as oxide, or nitride. In some embodiments, the insulating layer 37 may include a void.

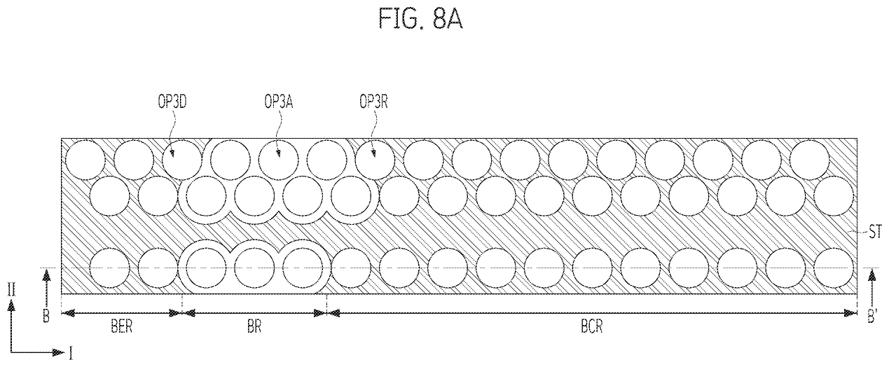

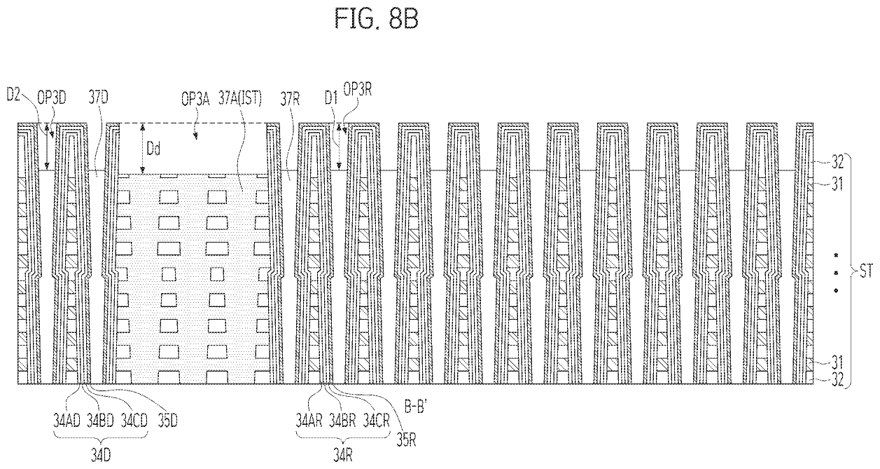

Referring to FIGS. 8A and 8B, an isolation insulating layer 37A may be formed in the isolation trench IST. The isolation insulating layer 37A may be formed by etching the insulating layer 37. In some embodiments, the insulating layer 37 may be etched in a dry etching process.

An insulating core 37R may be formed by etching a portion formed in the block center region BCR of the insulating layer 37. The insulating core 37R may be disposed in the channel layer 35R. A dummy insulating core 37D may be formed by etching the insulating layer 37 formed in the block edge region BER. The dummy insulating core 37D may be disposed in the dummy channel layer 35D. When forming the isolation insulating layer 37A, at least one of the insulating core 37R and the dummy insulating core 37D may be formed together.

The second material layers 32 of the boundary region BR may be etched. In a process of etching the insulating layer 37, the second material layers 32 of the boundary region BR may be exposed, and the second material layers 32 may be etched together. When etching the insulating layer 37, because the second material layers 32 of the block edge region BER and the block center region BSR are not exposed, the second material layers 32 of the boundary region BR may be selectively etched. A third opening OP3A disposed in the boundary region BR may be formed by etching the insulating layer 37 and the second material layers 32 of the boundary region BR. A third opening OP3R disposed in the block center region BCR may be formed by partially etching the insulating layer 37 of the block center region BCR. A third opening OP3D disposed in the block edge region BER may be formed by partially etching the insulating layer 37 of the block edge region BER. When forming the third opening OP3A, the third opening OP3R and the third opening OP3D may be formed.

The third openings OP3A, OP3R, and OP3D may be used for forming pads in a subsequent process. The third openings OP3A, OP3R, and OP3D may be disposed higher than an upper surface of the uppermost first material layer 31. The third openings OP3A, OP3R, and OP3D may have the same depth or different depths. In some embodiments, the third opening OP3A may have a wider width compared to the third opening OP3R and the third opening OP3D, and the third opening OP3A may be formed in a depth greater than the third opening OP3R and the third opening OP3D. A depth Dd may be greater than a depth D1 and a depth D2.

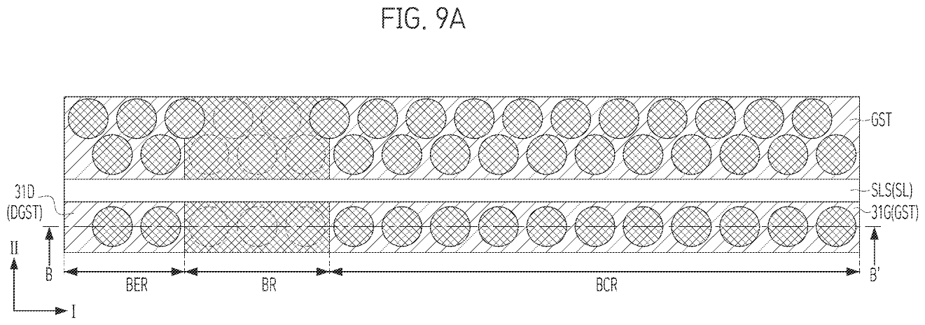

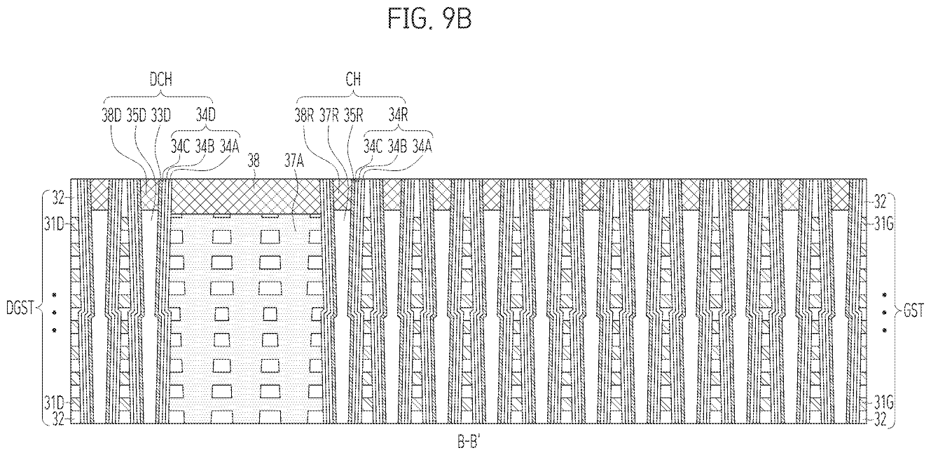

Referring to FIGS. 9A and 9B, a dummy pad 38 may be formed on the isolation insulating layer 37A. In some embodiments, the dummy pad 38 may be formed by forming a conductive layer in the third opening OP3A and planarizing the conductive layer until an upper surface of the stack ST is exposed. Through this, the dummy pad 38 may be formed in the third opening OP3A. The dummy pad 38 may include polysilicon. During planarizing, the conductive layer, the channel layer 35R, the dummy channel layer 35D, the memory layer 34R, and the dummy memory layer 34D may be planarized together.

When forming the dummy pad 38, a channel pad 38R and a dummy channel pad 38D may be formed. The channel pad 38R may be connected to the channel layer 35R and may be disposed on the insulating core 37R. The dummy channel pad 38D may be connected to the dummy channel layer 35D and may be disposed on the dummy insulating core 37D.

Through the above operations, channel structures CH disposed in the block center region BCR may be formed. The channel structures CH may include the channel layer 35R, the insulating core 37R, and the channel pad 38R. When forming the channel structure CHs, dummy channel structures DCH may be formed in the block edge region BER. The dummy channel structures DCH may include the dummy channel layer 35D, the dummy insulating core 37D, and the dummy channel pad 38D. When forming the channel structures CH, the isolation insulating layer 37A and the dummy pad 38 may be formed in the boundary region BR.

Subsequently, the first material layers 31 may be replaced with third material layers. In some embodiments, a slit SL extending in the first direction I through the stack ST may be formed. Subsequently, the first material layers 31 may be etched through the slit SL, and then conductive layers may be formed. Through this, the gate structure GST including gate lines 31G and the second material layers 32 alternately stacked in the block center region BCR may be formed. The dummy gate structure DGST may be formed in the block edge region BER. The dummy gate structure DGST may include dummy gate lines 31D and the second material layers 32 alternately stacked.

When the first material layers 31 are etched through the slit SL, the first material layers 31 of the boundary region BR may already be removed and the isolation insulating layer 37A may be formed. Therefore, the first material layers 31 of the block center region BCR and the block edge region BER may be etched, and the gate lines 31G of the block center region BCR and the dummy gate lines 31D of the block edge region BER may be naturally separated by the isolation insulating layer 37A. A process for separating the gate lines 31G and the dummy gate lines 31D might not be separately performed.

Subsequently, a slit structure SLS may be formed in the slit SL. The slit structure SLS may include at least one of an insulating material, a semiconductor material, and a conductive material. In some embodiments, the slit structure SLS may be a gap fill layer including an insulating material or a semiconductor material. The slit structure SLS may include a conductive contact plug and an insulating spacer.

According to the manufacturing method described above, the isolation insulating layer 17 and the dummy pad 18 may be formed using a process of forming the channel structure CH. Therefore, a cost associated with an additional process of forming the isolation insulating layer 17 and the dummy pad 18 may be reduced.

Before replacing the first material layers 31 with the third material layers, the isolation insulating layer 23A and the dummy pad 24 may be formed in the boundary region BR. Therefore, the block center region BCR and the block edge region BER may be separated by the isolation insulating layer 23A and the dummy pad 24, and the gate structures GST and the dummy gate structures DGST may be separated from each other.

Although embodiments according to the technical spirit of the present disclosure have been described with reference to the accompanying drawings, this is only for describing embodiments according to the concept of the present disclosure, and the present disclosure is not limited to the above-described embodiments. Within the scope of the technical spirit of the present disclosure, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a gate structure including gate lines and insulating layers alternately stacked;
a channel structure extending through the gate structure, the channel structure including a channel layer and a channel pad connected to the channel layer;
a dummy gate structure including stacked dummy gate lines;
a dummy channel structure extending through the dummy gate structure, the dummy channel structure including a dummy channel layer and a dummy channel pad connected to the dummy channel layer;
an isolation insulating layer disposed between the gate structure and the dummy gate structure; and
a dummy pad disposed on the isolation insulating layer between the gate structure and the dummy gate structure.

2. The semiconductor device of claim 1, wherein the isolation insulating layer includes stacked horizontal portions and vertical portions extending through the horizontal portions.

3. The semiconductor device of claim 2, wherein the horizontal portions are disposed to correspond to the gate lines and the dummy gate lines.

4. The semiconductor device of claim 2, wherein the insulating layers extend between the horizontal portions and between the dummy gate lines.

5. The semiconductor device of claim 1, wherein the channel pad, the dummy channel pad, and the dummy pad are disposed at substantially the same level.

6. The semiconductor device of claim 1, wherein a height of the dummy pad is greater than a height of the channel pad and a height of the dummy channel pad, and
a width of the dummy pad is greater than a width of the channel pad and a width of the dummy channel pad.

7. The semiconductor device of claim 1, wherein in a memory block, the dummy gate structure is disposed in a block edge region, the gate structure is disposed in a block center region, the isolation insulating structure is disposed in a boundary region, and the boundary region is disposed between the block edge region and the block center region.

8. The semiconductor device of claim 1, wherein the dummy pad includes polysilicon.

9. A semiconductor device comprising:
a gate structure including gate lines and insulating layers alternately stacked;
a dummy gate structure including stacked dummy gate lines;
an isolation insulating structure disposed between the gate structure and the dummy gate structure, the isolation insulating structure including stacked horizontal portions and vertical portions extending through the horizontal portions; and
a dummy pad disposed on the isolation insulating structure between the gate structure and the dummy gate structure.

10. The semiconductor device of claim 9, wherein the horizontal portions are disposed to correspond to the gate lines and the dummy gate lines.

11. The semiconductor device of claim 9, wherein the gate structure includes the gate lines and insulating layers alternately stacked, and
wherein the insulating layers extend between the horizontal portions and between the dummy gate lines.

12. The semiconductor device of claim 9, further comprising:
a channel structure extending through the gate structure, the channel structure including a channel layer and a channel pad connected to the channel layer; and
a dummy channel structure extending through the dummy gate structure, the dummy channel structure including a dummy channel layer and a dummy channel pad connected to the dummy channel layer.

13. The semiconductor device of claim 12, wherein the channel pad, the dummy channel pad, and the dummy pad are disposed at substantially the same level.

14. The semiconductor device of claim 12, wherein a height of the dummy pad is greater than a height of the channel pad and a height of the dummy channel pad, and
a width of the dummy pad is greater than a width of the channel pad and a width of the dummy channel pad.

15. The semiconductor device of claim 9, wherein in a memory block, the dummy gate structure is disposed in a block edge region, the gate structure is disposed in a block center region, the isolation insulating structure is disposed in a boundary region, and the boundary region is disposed between the block edge region and the block center region.
